(19) United States
(12) Patent Application Publication
(10) Pub. No.: US 2025/0083947 A1
(43) Pub. Date: Mar. 13, 2025

(54) MEMS MICROPHONE

(71) Applicant: Robert Bosch GmbH, Stuttgart (DE)

(72) Inventor: Jochen Reinmuth, Reutlingen (DE)

(21) Appl. No.: 18/817,340

(22) Filed: Aug. 28, 2024

(30) Foreign Application Priority Data
Sep. 8, 2023 (DE) 10 2023 208 733.2

(51) Int. Cl. B81B 3/00

(52) U.S. Cl. CPC B81B 3/0021; B81B 2201/0257; B81B 2203/0118; B81B 2203/0127; B81B 2203/0163; B81B 2203/04

(57) ABSTRACT

A MEMS microphone. The MEMS microphone includes: a membrane for absorbing sound pressure; a signal transduction element; and a lever element, coupled to the membrane and the signal transduction element. The lever element is configured, when the membrane is deflected, to generate a tilting movement and to transmit the generated tilting movement to the signal transduction element.

### CROSS REFERENCE

The present application claims the benefit under 35 U.S.C. § 119 of German Patent Application No. DE 10 2023 208 733.2 filed on Sep. 8, 2023, which is expressly incorporated herein by reference in its entirety.

### FIELD

The present invention relates to a MEMS microphone.

### BACKGROUND INFORMATION

China Patent Application No. CN 112383869 A describes a piezoelectric MEMS transducer.

European Patent Application No. EP 2 579 616 A1 describes an acoustic transducer.

German Patent Application No. DE 10 2021 206 005 A1 describes a micromechanical component for a microphone device.

German Patent Application No. DE 10 2014 212 340 A1 describes a microphone.

### SUMMARY

The present invention is based on the object of providing a MEMS microphone.

This object may be achieved by means of features of the present invention. Advantageous embodiments of the present invention are disclosed herein.

According to one aspect of the present invention, a MEMS microphone is provided. According to an example embodiment of the present invention, the MEMS microphone includes:
a membrane for absorbing sound pressure,
a signal transduction element, and
a lever element, coupled to the membrane and the signal transduction element,
   wherein the lever element is configured, when the membrane is deflected, to generate a tilting movement and to transmit the generated tilting movement to the signal transduction element.

According to the present invention, the above object is achieved by using a closed or partially closed membrane to detect a deflection due to sound pressure. The membrane is, for example, completely or partially connected to a substrate, generally a carrier, and spans, for example, a cavity in the substrate. According to an example embodiment of the present invention, it is provided that a lever element is used, which is coupled to the membrane and generates a tilting movement, which is transmitted to a signal transduction element. Based on the transmitted tilting movement, such a signal transduction element generates, for example, a capacitive signal, which depends on the deflection and thus on the sound pressure.

Thus, the membrane does not have to move relative to one or two fixed counter electrodes, which has the result that, on the one hand, the movement of the membrane in sound is almost undamped and, on the other hand, very good signal quality can be ensured.

A sensitive MEMS microphone with low noise and good linearity can thus be provided according to the present invention. Furthermore, it is thus possible to provide a MEMS microphone that has good media robustness. Furthermore, the MEMS microphone can be produced simply and cost-effectively.

Because the lever element transmits the deflection of the membrane to the signal transduction element, the membrane can be anchored, for example, on the outside of the substrate, generally the carrier, in particular anchored all around, so that it is possible to use a very thin membrane that nevertheless has a high degree of robustness. Furthermore, a very thin and therefore lightweight membrane can also be used.

For example, a polysilicon membrane is provided, which has a thickness of less than 4 μm, i.e., for example, a 2 μm thick membrane.

Due to this anchoring, very large but lightweight membranes and thus sensitive membranes can be used, for example. The membrane as a sound capture element thus does not have to stabilize itself but is stabilized, for example, by its suspension from the substrate, generally the carrier.

Furthermore, according to an example embodiment of the present invention, the lever element can, for example, be constructed in such a way that it is lightweight but stiff. The moving parts of the signal transduction element can also be chosen to be lightweight but robust.

Lightweight and stiff means in particular that the natural frequency of the pure lever element is high, for example greater than 30 kHz.

In summary, it is advantageously made possible to design a microphone with a high natural frequency and, at the same time, high sensitivity in such an arrangement. The natural frequency can, for example, be specifically adjusted by layer stress in the membrane and/or by suspension springs between the membrane and the substrate, generally the carrier, so that high natural frequencies, in particular a natural frequency greater than 15 kHz, can thus be achieved even for large membranes. By clamping the membrane to the substrate, a bypass for the air flow can, for example, be completely or partially prevented. Furthermore, this can also achieve that the component has good robustness against particles and liquids.

The abbreviation “MEMS” stands for “microelectromechanical system.”

In one example embodiment of the MEMS microphone of the present invention, it is provided that the lever element is connected to the membrane eccentrically or centrically in relation to the membrane.

This brings about the technical advantage that the lever element is particularly efficiently connected to the membrane.

With a centric arrangement, a correspondingly large deflection of the membrane can be efficiently transmitted to the signal transduction element.

In one example embodiment of the MEMS microphone, it is provided that recesses are provided in the membrane in the case of a centric connection in order to compensate for different tilting movements between the lever element and the membrane.

This brings about the technical advantage that the different tilting movements between the lever element and the membrane can be efficiently compensated for.

In one example embodiment of the MEMS microphone of the present invention, it is provided that the lever element is connected to the membrane at a connection point in such a way that a tilting of the membrane substantially coincides with a tilting movement of the lever element.

This brings about the technical advantage that a particularly sensitive MEMS microphone is thereby provided, in which no additional stress is caused in the signal transduction element, in the lever element or in the membrane when the membrane is deflected.

In one example embodiment of the MEMS microphone of the present invention, it is provided that the lever element is coupled to the membrane at a distance therefrom in order to prevent the membrane from striking the lever element.

This brings about the technical advantage that the membrane can be efficiently prevented from striking the lever element in the event of large deflections.

In one example embodiment of the MEMS microphone of the present invention, it is provided that the lever element is connected to the membrane via a mechanical connecting element which, in a portion, has at least three times the height of a membrane thickness and which covers a surface of the membrane by less than 25% in relation to the surface of the membrane in order to compensate for different tilting movements between the lever element and the membrane. The term surface here refers in particular to the surface of a main extension plane of the membrane. In particular, the term surface refers to a horizontal surface of the membrane when the membrane is in the rest position.

This brings about the technical advantage that the different tilting movements between the lever and the membrane can be compensated for.

In one example embodiment of the present invention, the MEMS microphone comprises a carrier, in particular a substrate, on which the membrane, the signal transduction element and the lever element are arranged, wherein the membrane is at least partially connected to, in particular suspended from, the carrier via at least one spring.

This, for example, brings about the technical advantage that stress can efficiently be reduced.

In one example embodiment of the MEMS microphone, it is provided that the at least one spring is spiral-shaped.

This, for example, brings about the technical advantage that stress in the layer can be compensated for by a rotational movement of the membrane. The membrane properties thus no longer depend on the layer stress of the membrane. Furthermore, the suspensions of the membrane can be designed to be particularly soft.

In one example embodiment of the present invention, the MEMS microphone comprises a stop structure for the membrane in at least one of two deflection directions of the membrane.

This brings about the technical advantage that the membrane can be efficiently prevented from striking the lever element in the event of an overload.

The wording “at least one” means “one or more”.

This means that the phrase “in at least one of two deflection directions of the membrane” means the following: in one or in two of the two deflection directions of the membrane.

One deflection direction, which may also be referred to as the first deflection direction, is directed toward the carrier. Another deflection direction, which may also be referred to as the second deflection direction, is directed away from the carrier.

In one example embodiment of the MEMS microphone of the present invention, it is provided that the stop structure has a carrier region of the carrier that is formed below the at least one spring as a stop for the membrane in a deflection direction toward the carrier.

This, for example, brings about the technical advantage that the stop structure can be formed efficiently.

In one example embodiment of the MEMS microphone of the present invention, it is provided that the stop structure has a cover that is formed above the at least one spring as a stop for the membrane in a deflection direction away from the carrier.

This brings about the technical advantage that the stop structure can be formed efficiently.

In one example embodiment of the present invention, the MEMS microphone comprises a carrier, in particular a substrate, on which the membrane, the signal transduction element and the lever element are arranged, wherein the membrane is connected directly to the carrier.

This brings about the technical advantage that the membrane is efficiently connected to the carrier.

The signal transduction element may, for example, be the signal transduction element according to German Patent Application No. DE 10 2021 206 005. Accordingly, the signal transduction element may be a transduction element that generates a capacitive signal within a hermetically sealed region, wherein a pressure lower than the external pressure is enclosed in this region.

The signal transduction element within the meaning of the description converts a tilting movement, transmitted by the lever element, into a signal, for example a voltage signal. The signal transduction element is, for example, configured to convert a tilting movement, transmitted by the lever element, into a signal, for example a voltage signal. The signal is, for example, an electrical signal. For example, the signal transduction element comprises two opposing electrodes, which form a capacitor, wherein one of the two electrodes is a fixed electrode, and wherein the other of the two electrodes is a movable electrode to which the tilting movement is transmitted by the lever element. A voltage applied to the capacitor depends in particular on a distance between the two electrodes. Since the distance changes as a result of the transmitted tilting movement, the applied voltage changes accordingly so that the deflection of the membrane can be deduced from a voltage measurement. The applied voltage thus depends on the deflection of the membrane.

According to an example embodiment of the present invention, the signal transduction element comprises, for example, two fixed counter electrodes: a first counter electrode and a second counter electrode, which are arranged on the carrier. The fixed counter electrodes can also be referred to as stator electrodes.

Provided above the two counter electrodes is, for example, a movable electrode of the signal transduction element, which can perform a tilting movement and the movement of which is, for example, determined through a measurement of the capacitance to one of the two counter electrodes in each case. The movable electrode may also be referred to as an actuator electrode. The lever element is, for example, configured, when the membrane is deflected, to generate a tilting movement and to transmit the generated tilting movement to the movable electrode. The deflection of the membrane is thus transmitted to the movable electrode of the signal transduction element by means of the lever element.

According to an example embodiment of the present invention, the MEMS microphone comprises, for example, a closure layer, which closes or seals the two counter electrodes and the movable electrode. The closure layer thus in particular ensures the closure of this structure of counter electrodes and movable electrode in order, for example, to enclose a vacuum in this region in order, for example, to reduce the attenuation.

A carrier within the meaning of the description is, for example, a substrate.

A membrane may, for example, be formed as a MEMS functional layer.

Generally, elements, for example the membrane, lever element, counter electrode, movable electrode and/or closure layer, of the MEMS microphone can each be formed as MEMS functional layers.

The present invention is explained in more detail below using preferred exemplary embodiments.

### BRIEF DESCRIPTION OF THE DRAWINGS

FIG. 1 shows a first MEMS microphone according to an example embodiment of the present invention in a cross-sectional view.

FIG. 2 shows a second MEMS microphone according to an example embodiment of the present invention in a cross-sectional view.

FIG. 3 shows a third MEMS microphone according to an example embodiment of the present invention in a cross-sectional view.

FIG. 4 shows a fourth MEMS microphone according to an example embodiment of the present invention in a cross-sectional view.

FIG. 5 shows the fourth MEMS microphone according to an example embodiment of the present invention in a plan view.

### DETAILED DESCRIPTION OF EXAMPLE EMBODIMENTS

In the following, the same reference signs can be used for identical features.

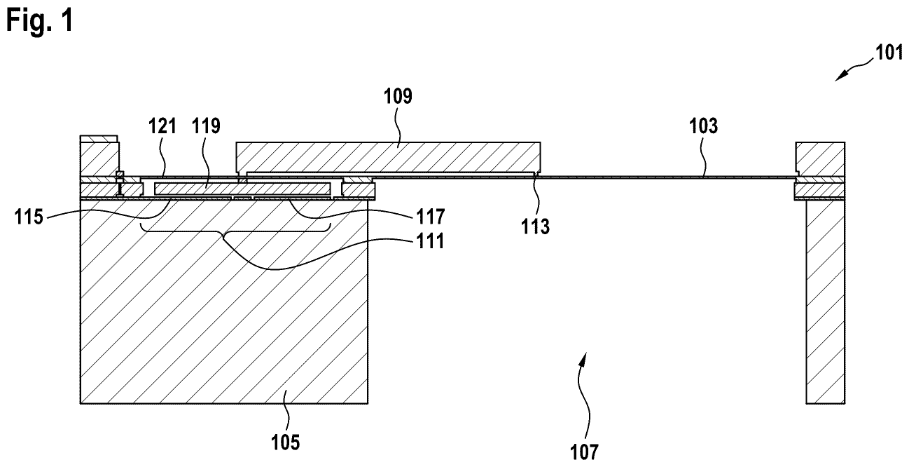

FIG. 1 shows a first MEMS microphone 101 in a cross-sectional view.

The first MEMS microphone 101 comprises a membrane 103 for absorbing sound pressure. The membrane 103 is connected to a substrate 105 and spans a cavity 107 in the substrate 105.

The first MEMS microphone 101 comprises a lever element 109, which is coupled to the membrane 103. The lever element 109 is furthermore coupled to a signal transduction element 111 of the first MEMS microphone 101. The lever element 109 is configured, when the membrane 103 is deflected, to generate a tilting movement and to transmit the generated tilting movement to the signal transduction element 111.

In other words, the lever element 109 is coupled to the membrane 103 and, when the membrane 103 is deflected, generates a tilting movement, which is transmitted to the signal transduction element 111.

Since the membrane 103 does not have to move relative to one or two fixed counter electrodes, the movement of the membrane 103 in sound is almost undamped on the one hand and very good signal quality can be ensured on the other hand.

In the first MEMS microphone 101, the lever element 109 is connected to the membrane 103 eccentrically in relation to the membrane 103. A connection point 113 of the lever element 109 on the membrane 103 is selected in such a way that a tilting of the membrane 103 coincides with the tilting movement of the lever element 109, which is fixed to the signal transduction element 111. This makes it possible to provide a particularly sensitive MEMS microphone, in which no additional stress is caused in the signal transduction element 111, in the lever element 109 or in the membrane 103 when the membrane 103 is deflected.

The signal transduction element 111 comprises two fixed counter electrodes: a first counter electrode 115 and a second counter electrode 117, which are arranged on the substrate 105. The fixed counter electrodes 115, 117 can also be referred to as stator electrodes.

Provided above the two counter electrodes 115, 117 is a movable electrode 119 of the signal transduction element 111, which can perform a tilting movement and the movement of which is determined through a measurement of the capacitance to one of the two counter electrodes 115, 117 in each case. The movable electrode 119 may also be referred to as an actuator electrode.

The MEMS microphone 101 comprises a closure layer 121, which closes or seals the two counter electrodes 115, 117 and the movable electrode 119. The closure layer 121 thus ensures the closure of this structure of counter electrodes 115, 117 and movable electrode 119 in order, for example, to enclose a vacuum in this region in order, for example, to reduce the attenuation.

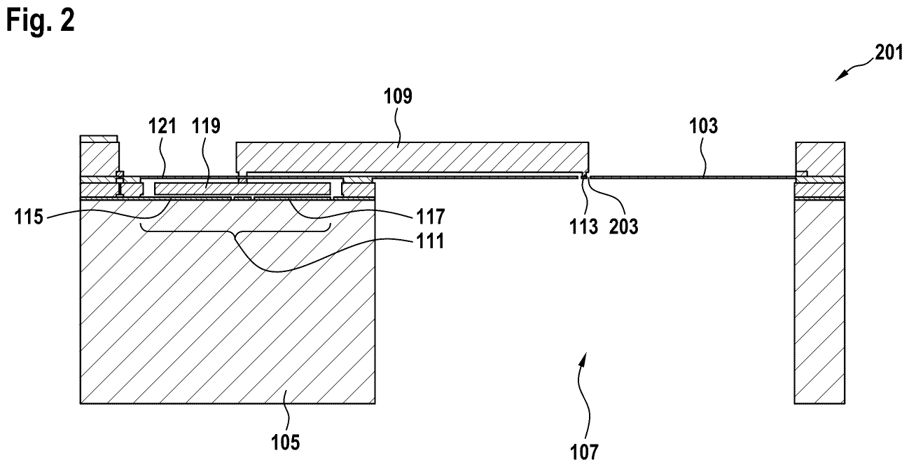

FIG. 2 shows a second MEMS microphone 201 in a cross-sectional view.

In the second MEMS microphone 201, the lever element 109 is connected in the membrane center in order to transmit as large as possible a deflection to the signal transduction element 111. The membrane 103 has recesses 203 in the membrane center, which can bring about compensation for the different tilting movements between the lever element 109 and the membrane 103.

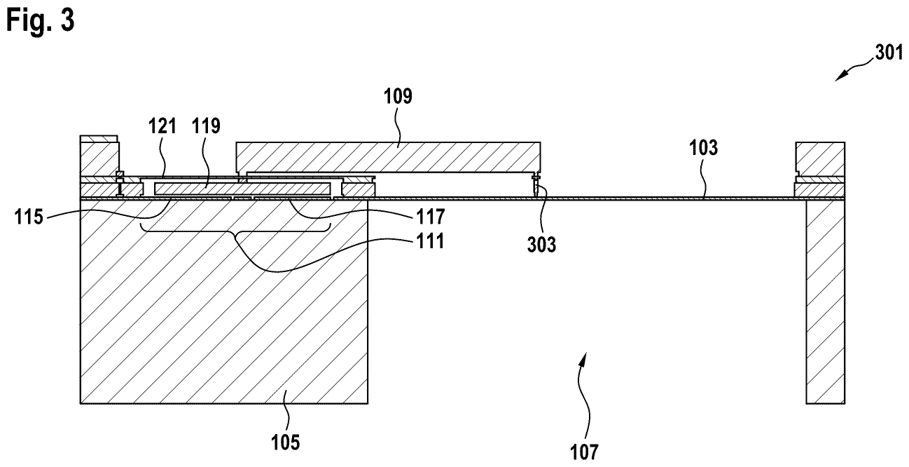

FIG. 3 shows a third MEMS microphone 301 in a cross-sectional view. Using a connecting element 303 brings about a distance between the membrane 103 and the lever element 109 in order to prevent the membrane 103 from striking the lever element 109 in the event of large deflections of the membrane 103. The connecting element 303 can be particularly thin and high in order to be able to bring about compensation for the different tilting movements between the lever element 109 and the membrane 103.

It is particularly advantageous to use membranes that are particularly thin but experience tensile stress. This allows large surfaces to be spanned, and the natural frequency of the membrane can be adjusted via the tensile stress, wherein the low mass of the membrane results in high sensitivity.

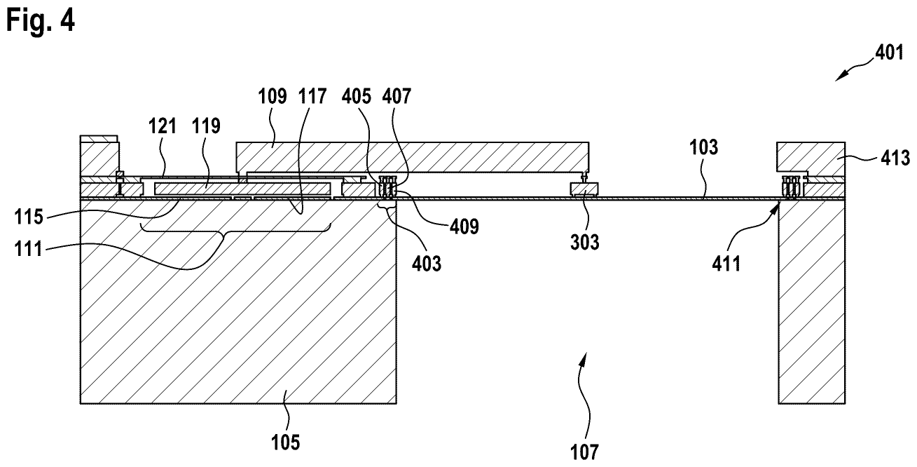

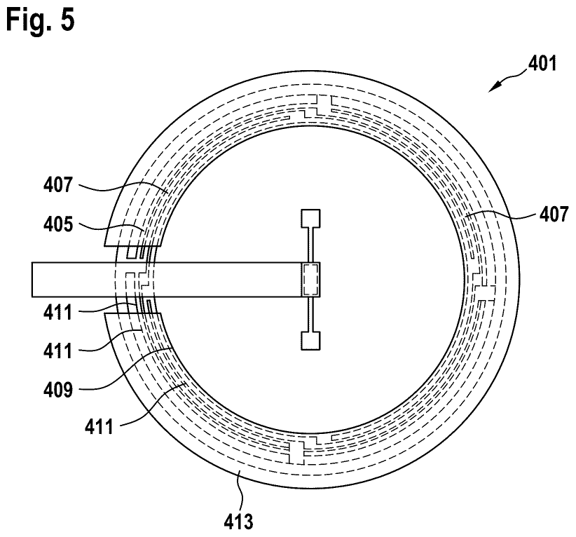

For applications in which layers with tensile stress are not available, or for arrangements in which the layers are also used to construct the signal transduction element, arrangements as shown in FIGS. 4 and 5 are particularly advantageous.

FIG. 4 shows a fourth MEMS microphone 401 in a cross-sectional view.

At the edge of the membrane 103, the membrane 103 is suspended from the substrate 105 via a three-part spring 403. A first spring part 405 denotes the part of the spring 403 that is coupled to the substrate 105. The second spring part 407 substantially denotes the center part of the spring 403. The third part 409 denotes the part of the spring that is coupled to the membrane 103.

The spring 403 or the three spring parts 405, 407, 409 have a spiral shape. As a result, stress in the layer can be compensated for by a rotational movement of the membrane 103. The membrane properties thus no longer depend on the layer stress of the membrane 103. Furthermore, the suspension of the membrane 103 can also be designed to be particularly soft.

For example, multiple layers are utilized or used to adjust a small distance between the substrate 105 and the spring 403 and between the spring 403 and the membrane 103 in order to keep an acoustic leakage path as small as possible.

A small distance is, for example, a distance between 3 μm and 0.3 μm, wherein 3 μm and 0.3 μm are also included. Distances between 3 μm and 0.3 μm, wherein 3 μm and 0.3 μm are also included, can thus, for example, be defined as small distances.

Furthermore, for example, both a substrate region 411 and a cover with a further layer 413 may be provided above and below the springs, wherein the further layer 413 may, for example, be the same layer from which the lever element 109 is also formed. In this way, an acoustic leakage path can advantageously be further reduced and, at the same time, a stop structure for the membrane in both deflection directions, i.e., in one case toward the substrate 105 and in one case away from the substrate 105, can also be advantageously provided. Furthermore, this can advantageously also prevent the membrane 103 from striking the lever element 109 in the event of an overload.

FIG. 5 shows the fourth MEMS microphone 401 in a plan view.

What is claimed is:

1. A MEMS microphone, comprising:
a membrane configured to absorb sound pressure;
a signal transduction element; and
a lever element, coupled to the membrane and the signal transduction element, wherein the lever element is configured to generate, when the membrane is deflected, a tilting movement, and to transmit the generated tilting movement to the signal transduction element.

2. The MEMS microphone according to claim 1, wherein the lever element is connected to the membrane eccentrically or centrically in relation to the membrane.

3. The MEMS microphone according to claim 2, wherein the level is connected to the membrane centrically in relation to the membrane, and recesses are provided in the membrane to compensate for different tilting movements between the lever element and the membrane.

4. The MEMS microphone according to claim 1, wherein the lever element is connected to the membrane at a connection point in such a way that a tilting of the membrane substantially coincides with a tilting movement of the lever element.

5. The MEMS microphone according to claim 1, wherein the lever element is coupled to the membrane at a distance from the lever in order to prevent the membrane from striking the lever element.

6. The MEMS microphone according to claim 1, wherein the lever element is connected to the membrane via a mechanical connecting element which, in a portion, has at least three times the height of a membrane thickness and which covers a surface of the membrane by less than 25% in relation to the surface of the membrane in order to compensate for different tilting movements between the lever element and the membrane.

7. The MEMS microphone according to claim 1, further comprising a carrier, which includes a substrate, on which the membrane, the signal transduction element, and the lever element are arranged, wherein the membrane s at least partially connected to and suspended from, the carrier via at least one spring.

8. The MEMS microphone according to claim 7, wherein the at least one spring is spiral-shaped.

9. The MEMS microphone according to claim 7, further comprising a stop structure for the membrane in at least one of two deflection directions of the membrane.

10. The MEMS microphone according to claim 9, wherein the stop structure as a carrier region of the carrier that is formed below the at least one spring as a stop for the membrane in a deflection direction toward the carrier.

11. The MEMS microphone according to claim 9, wherein the stop structure has a cover that is formed above the at least one spring as a stop for the membrane in a deflection direction away from the carrier.

12. The MEMS microphone according to claim 1, further comprising a carrier, including a substrate, on which the membrane, the signal transduction element, and the lever element are arranged, wherein the membrane is directly connected to the carrier.
